(19) United States
(12) Patent Application Publication
(10) Pub. No.: US 2025/0346114 A1
(43) Pub. Date: Nov. 13, 2025

(54) Die Crack Detection System

(71) Applicant: NVIDIA Corporation, Santa Clara, CA (US)

(72) Inventors: Krishnamraju Kurra, Austin, TX (US); Gunaseelan Ponnuvel, San Jose, CA (US); Anand Sudhini, Livermore, CA (US); Tezaswi Raja, San Jose, CA (US); Daniel Nguyen, San Jose, CA (US)

(73) Assignee: NVIDIA Corporation, Santa Clara, CA (US)

(21) Appl. No.: 19/050,532

(22) Filed: Feb. 11, 2025

Related U.S. Application Data
(60) Provisional application No. 63/644,255, filed on May 8, 2024.

(51) Int. Cl. B60K 28/10; B60R 16/03; G01R 31/3181; G01R 31/3185; G07C 5/08

(52) U.S. Cl. CPC B60K 28/10; B60R 16/0315; G01R 31/31813; G01R 31/318597; G07C 5/0808; G07C 5/085

(57) ABSTRACT

An IC package includes a die and an elongate conductive trace formed adjacent to at least one peripheral edge of the die. Test logic in the package performs a die crack test by applying a test pattern to a first end of the conductive trace and sensing a response pattern at a second end of the conductive trace. The package is configured to operate in at least two distinct modes, including a manufacturing test mode in which a die crack test result is communicated from the package out of a JTAG port, and a field test mode in which the die crack test result is communicated from the package out of a data transfer port. A vehicle computer system may perform a fail safe action based on the die crack test result.

### CROSS REFERENCE TO RELATED APPLICATIONS

This application claims benefit to the filing date of prior U.S. Patent Application No. 63/644,255, filed on 2024 May 8 (the “Provisional Application”), the contents of which are hereby incorporated by reference as if entirely set forth herein. In the event of conflict between the meaning of a term used in this document and the same or a similar term used in the Provisional Application or in another document incorporated herein by reference, the meaning associated with this document shall control.

### BACKGROUND

During the process in which a silicon wafer is sliced to produce individual integrated circuit dies, cracks can occur in the dies. While large cracks can be detected using known techniques at the time of manufacture, existing quality control methods often do not detect small cracks that may occur near the edges of a die. For example, a small crack located near the edge of a die that does not affect logic circuitry in the die will not be detected by conventional automated test equipment (“ATE”) at the time of manufacture because the tests run by such equipment only cover functional correctness of the logic circuitry of the die.

Moreover, after a die has been packaged and has been embedded in a product that is deployed in the field, repeated heating and cooling of the die during operation of the product can cause a small crack to increase in size. Eventually, the crack may corrupt logic circuitry on the die and cause it to fail.

A need therefore exists for techniques that can be used to detect die cracks both at the time of manufacture and also during the life of a product that has been deployed in the field.

### BRIEF DESCRIPTION OF THE DRAWINGS

FIG. 1 is an oblique view of an integrated circuit package having a JTAG port and a separate data transfer port in accordance with embodiments.

FIG. 2 is a schematic view illustrating an elongate conductive trace and die crack test logic in the integrated circuit package of FIG. 1, in accordance with embodiments.

FIGS. 3 and 4 are top and side detail views, respectively, of a portion of the elongate conductive trace of FIG. 2, in accordance with embodiments.

FIG. 5 is a block diagram schematically illustrating the die crack test logic of FIG. 2 in more detail, in accordance with embodiments.

FIG. 6 is a block diagram schematically illustrating the test logic and the transmit, receive, and loopback paths of FIG. 5 in more detail, in accordance with embodiments.

FIG. 7 is a block diagram schematically illustrating a die crack detection system that includes a host computer system and the integrated circuit package of FIGS. 1 and 2, in accordance with embodiments.

FIG. 8 is a flow diagram illustrating example functionality of the die crack detection system of FIG. 7, in accordance with embodiments.

FIG. 9 is a block diagram schematically illustrating a vehicle that includes the die crack detection system of FIG. 7, in accordance with embodiments.

FIG. 10 is a flow diagram illustrating example functionality of the vehicle and die crack detection system of FIG. 9, in accordance with embodiments.

### DETAILED DESCRIPTION

This disclosure describes multiple embodiments by way of example and illustration. It is intended that characteristics and features of all described embodiments may be combined in any manner consistent with the teachings, suggestions, and objectives contained herein. Thus, phrases such as “in an embodiment,” “in one embodiment,” and the like, when used to describe embodiments in a particular context, are not intended to limit the described characteristics or features only to the embodiments appearing in that context.

The phrases “based on” or “based at least in part on” refer to one or more inputs that can be used directly or indirectly in making some determination or in performing some computation. Use of those phrases herein is not intended to foreclose using additional or other inputs in making the described determination or in performing the described computation. Rather, determinations or computations so described may be based either solely on the referenced inputs or on those inputs as well as others.

The phrase “configured to” as used herein means that the referenced item, when operated, can perform the described function. In this sense, an item can be “configured to” perform a function even when the item is not operating and therefore is not currently performing the function. Use of the phrase “configured to” herein does not necessarily mean that the described item has been modified in some way relative to a previous state.

“Coupled” as used herein refers to a connection between items. Such a connection can be direct or can be indirect, such as through connections with other intermediate items.

Terms used herein such as “including,” “comprising,” and their variants, mean “including but not limited to.”

Articles of speech such as “a,” “an,” and “the” as used herein are intended to serve as singular as well as plural references except where the context clearly indicates otherwise. For example, articles of speech such as “a,” “an,” and “the,” when used in a claim or sentence subsequent to words such as “including,” “comprising,” or their variants, mean “one or more.”

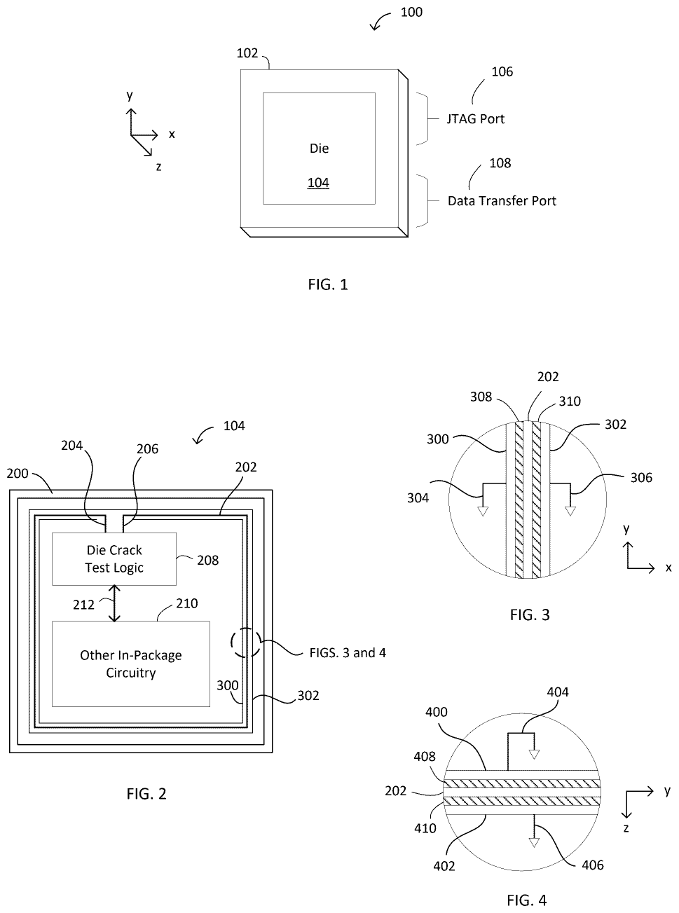

FIG. 1 is an oblique view of an example integrated circuit (“IC”) package 100 in accordance with embodiments. The package includes a substrate 102 having one or more integrated circuit dies mounted thereon, such as an integrated circuit die 104, and having a set of externally accessible conductors disposed on one or more sides thereof. At least some of the conductors are coupled to circuitry disposed on or inside the die. The package may be constructed using any of a variety of known packaging techniques, and the externally accessible conductors may be arranged on the package in any suitable fashion. For example, the conductors may be arranged in a pin grid array (“PGA”) fashion or in a ball grid array (“BGA”) fashion.

A first subset 106 of the externally accessible conductors is dedicated to Joint Test Action Group (“JTAG”) functionality and is therefore referred to herein as a JTAG port. A second subset 108 of the externally accessible conductors, distinct from the first subset, provides a data transfer port by means of which data unrelated to JTAG functionality may be communicated into or out of the integrated circuit package. In some embodiments, the data transfer port may comprise a Peripheral Component Interconnect Express (“PCIe”) port. In other embodiments, other types of data transfer ports may be used.

FIG. 2 is a schematic view conceptually illustrating several components of die 104. The die includes a seal ring area 200 around its peripheral edges and an elongate conductive trace 202. The elongate conductive trace may be disposed in a variety of locations on or within the die and may have any size and shape suitable to the application. In some embodiments, for example, the trace may have a width on the order of 0.08 micrometers and may have a length much longer than its width. In the embodiment shown, the elongate conductive trace is disposed adjacent to each of the four peripheral edges of the die near the seal ring area. In other embodiments, the elongate conductive trace may be disposed completely or partially within the seal ring area itself. In the illustrated embodiment, the elongate conductive trace forms a two-ended ring. Each of its two ends 204, 206 is coupled to die crack test logic 208. The die crack test logic is, in turn, coupled to other in-package circuitry 210 by one or more communication lines or buses 212.

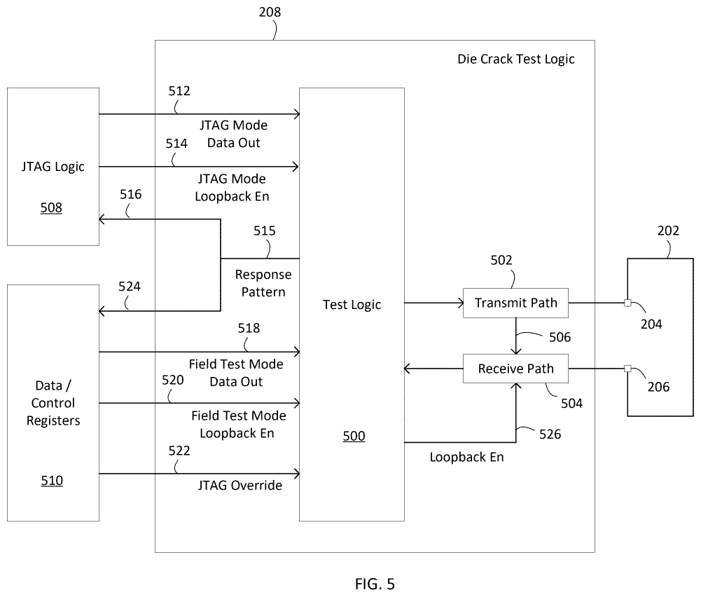

In some embodiments, coaxial shielding may be added around the elongate conductive trace to reduce the coupling of electromagnetic interference noise onto the elongate conductor. Such shielding may be particularly beneficial, for example, for embodiments in which a digital signal is communicated through the elongate trace at a relatively high frequency. An example of such shielding is shown in the drawing and is illustrated in more detail at FIG. 3 and FIG. 4, which are top and side views, respectively, of the portion of the elongate conductive trace enclosed by the dashed circle of FIG. 2.

In general, such coaxial shielding may constructed by providing one or more conductive ground traces on or in the die such that the ground traces are oriented coaxially with the elongate conductive trace but are separated from the trace by dielectric boundaries. By way of example, FIG. 3 illustrates a left conductive trace 300 and a right conductive trace 302. Each is oriented coaxially with elongate conductive trace 202, and each is coupled to an electrical ground as indicated at 304 and 306. Dielectric boundaries 308, 310 separate the left and right conductive ground traces from elongate conductive trace 202. By way of further example, FIG. 4 illustrates an upper conductive trace 400 and a lower conductive trace 402. Each is oriented coaxially with elongate conductive trace 202, and each is coupled to an electrical ground as indicated at 404 and 406. Dielectric boundaries 408, 410 separate the upper and lower conductive ground traces from elongate conductive trace 202. In other embodiments, other structures may be employed to achieve coaxial shielding if such shielding is desired.

In various embodiments, more than one elongate conductive trace may be implemented on different layers of a single integrated circuit die, with corresponding test logic, driving circuitry, data registers, control registers, and interfaces provided for each of the respective elongate test traces on the die.

FIG. 5 is a block diagram schematically illustrating the die crack test logic of FIG. 2 in more detail. The die crack test logic is configured to perform a die crack test by applying an electrical test pattern to one end (e.g., end 204) of elongate conductive trace 202 and by sensing an electrical response pattern at the other end (e.g., end 206) of the conductive trace. In general, the test pattern may comprise any electrical signal. In some embodiments, the test pattern may comprise a first binary sequence, such as any series of logical ones and zeroes. In the latter embodiments, the response pattern may comprise a second binary sequence.

The test pattern may be clocked through the elongate conductive trace at any suitable speed, taking into account an upper limit determined by the resistive-capacitive (“RC”) constant represented by the elongate conductive trace, and by employing one or more driver stages (to be further described below) to accommodate the RC load represented by the trace. The two binary sequences may be tested for equality and, if they are found to be equal, a result of the die crack test result may indicate that the no crack has been detected on the die. If, on the other hand, the test pattern and the response pattern are found to be not equal, then a die crack test result may indicate that a crack has been detected on the die.

In some embodiments, the die crack test logic itself may be configured to compare the test pattern with the response pattern and to thereby determine whether a crack has been detected on the die. In other embodiments, the die crack test logic may simply communicate the response pattern to other logic located elsewhere in the integrated circuit package or in a host system, and the other logic may make the determination as to whether a crack has been detected on the die. In any such embodiments, a die crack test result may include the response pattern, or may simply include a pass/fail result, or may include both a pass/fail result as well as the response pattern.

In the illustrated embodiment, test logic 500 is configured to transmit the test pattern via a transmit path 502 disposed between the test logic and the first end 204 of the elongate conductive trace, and to receive the response pattern via a receive path 504 disposed between the test logic and the second end 206 of the elongate conductive trace. In some embodiments, the die crack test logic may also include a loopback mode (to be further described below). In such embodiments, when the loopback mode is active, test logic 500 receives the response pattern via a loopback path 506 that bypasses the elongate conductive trace. The loopback mode may be used, for example, during tests whose purpose is to verify correct behavior of the die crack detection system itself.

Test logic 500 is communicatively coupled to JTAG logic 508 and to a set of data and/or control registers 510, as shown. The JTAG logic provides a JTAG mode data out signal 512 and a JTAG mode loopback enable signal 514 to the test logic, and receives the response pattern 515 from the test logic at a JTAG mode response pattern input 516. The data/control registers provide a field test mode data out signal 518, a field test mode loopback enable signal 520, and a JTAG override signal 522 to the test logic. The data/control register receive the response pattern from the test logic at a field test mode response pattern input 524. The test logic, in turn, provides a loopback enable signal 526 to the receive path.

By way of example, the JTAG logic may include one or more JTAG data registers and one or more JTAG control registers. Similarly, data/control register logic 510 may include one or more field test data registers and one or more field test control registers. By way of example, the JTAG data registers may include a JTAG test pattern register configured to supply a test pattern to the test logic via JTAG mode data out signal 512, and may include a JTAG response pattern register configured to receive a response pattern via JTAG response pattern input 516. The JTAG control registers may include a JTAG control register configured to supply a value to JTAG mode loopback enable signal 514. Similarly, the field test data registers may include a first field test data register configured to supply a test pattern to the test logic via field test mode data out signal 518, and may include a second field test data register configured to receive a test pattern via response pattern input 524. The field test control registers may include a field test control register configured to supply a value to field test mode loopback enable signal 520. A further control register may be configured to supply a value to JTAG override signal 522. Any such registers may be accessed via one or more address/data buses coupled to the data/control register logic and to the JTAG logic.

In operation, an entity such as a hardware test controller or software executing in a host computer system may write a test pattern into one or more of the data registers and may read a response pattern from another one or more of the data registers. Such an entity may also write control values into any one or more of the control registers in the same manner. In some embodiments, the data registers may comprise one or more shift registers so that, for example, the contents of a test pattern register may be clocked onto the transmit path, and the state of the receive path may be clocked into a response pattern register. Similarly, any of the aforementioned entities may write control information, such as a JTAG override bit and/or a loopback enable bit, into one or more of the control registers as appropriate to configure the operation of the die crack detection system.

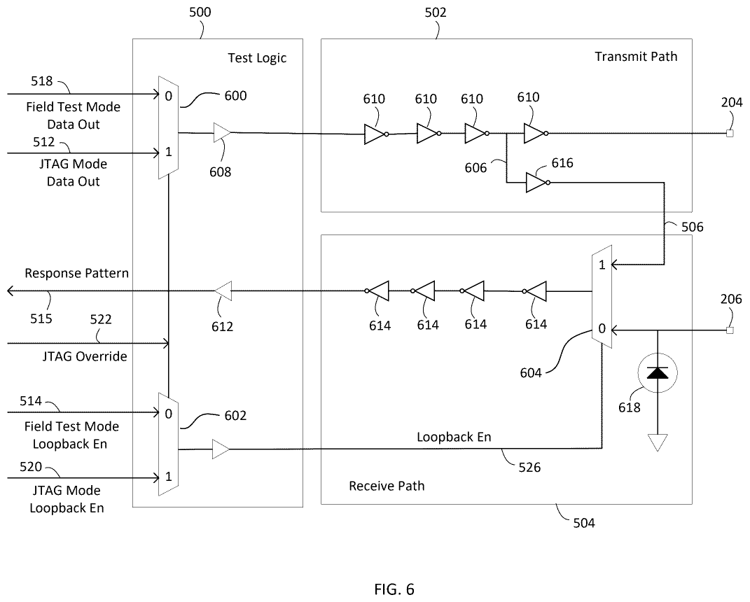

FIG. 6 is a block diagram schematically illustrating an example embodiment of the test logic and of the transmit, receive, and loopback paths of FIG. 5 in more detail. As can be seen in the drawing, the test logic includes a test pattern multiplexer 600 and a loopback enable multiplexer 602, while the receive path includes a receive path multiplexer 604. The data output of the test pattern multiplexer is coupled to the first end 204 of the elongate conductive trace via several buffer/driver stages 608/610. The data output of the receive path multiplexer provides a response pattern signal 515 via several buffer/driver stages 612/614. In various embodiments, different numbers of buffer/driver stages may be used than are shown in the illustrated embodiment. Note that, in the illustrated embodiment, the same number of buffer/driver stages are included in the receive path as are included in the transmit path. In addition, a driver stage 616 is included in loopback path 506 such that, when loopback mode is enabled, the bypassed transmit path includes the same number of buffer/driver stages as does the receive path. Note also that, in the illustrated embodiment, several of the driver stages are logical inverters, and the same number of logical inverters are included in the receive path as are included in transmit path and in the loopback path. In other embodiments, other numbers and types of driver stages may be used.

The test pattern multiplexer and the loopback enable multiplexer both have their select inputs coupled to JTAG override signal 522. Accordingly, when the JTAG override signal is not asserted, the field test mode data out signal provides the content for the transmit path, and the field test mode loopback enable signal determines the state of loopback enable signal 526. When the JTAG override signal is asserted, however, JTAG mode data out signal 512 provides the content for the transmit path, and the JTAG mode loopback enable signal determines the state of loopback enable signal 526. In this sense, the JTAG override signal serves as a manufacturing test mode enable signal.

The select input of the receive path multiplexer is coupled to loopback enable signal 526. Accordingly, when the loopback enable signal is not asserted, the content of the receive path is provided by the second end 206 of the elongate conductive trace. When the loopback enable signal is asserted, however, the content of the receive path is provided by loopback path 506, which follows the state of the transmit path via a tap 606 into the transmit path located upstream of the first end 204 of the elongate conductive trace.

In some embodiments, a static discharge protection diode 618 may be coupled between the second end 206 of the elongate conductive trace and an electrical ground node, as shown. The breakdown voltage of the diode may be chosen such that the diode does not conduct when the voltage levels at node 206 are within expected operational limits, but does conduct when the voltage on the node exceeds such limits. As a non-limiting example, a breakdown voltage on the order of 5V may be chosen in embodiments for which Vdd and logic levels are expected to be lower than 5V. In this way, a static discharge from the elongate conductive trace may be safely shunted away from the data input of the receive path multiplexer, thus protecting the multiplexer from damage.

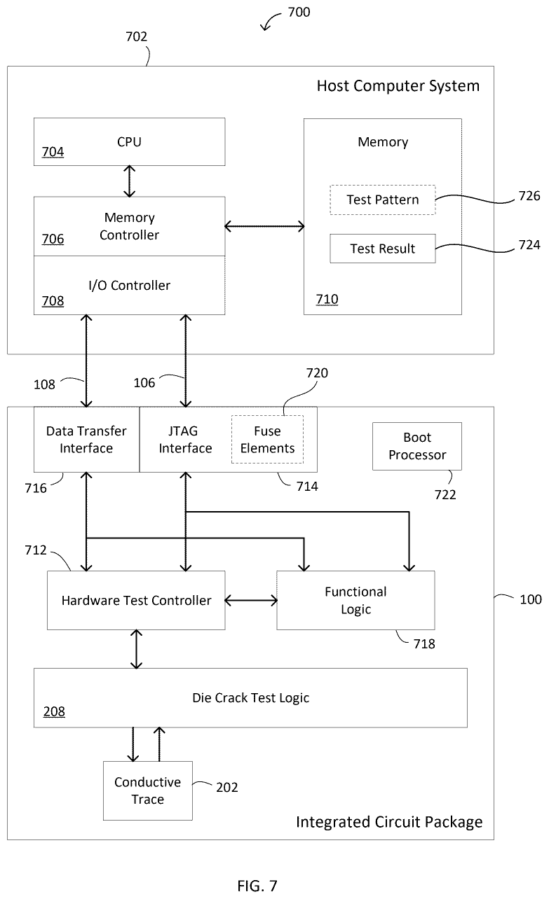

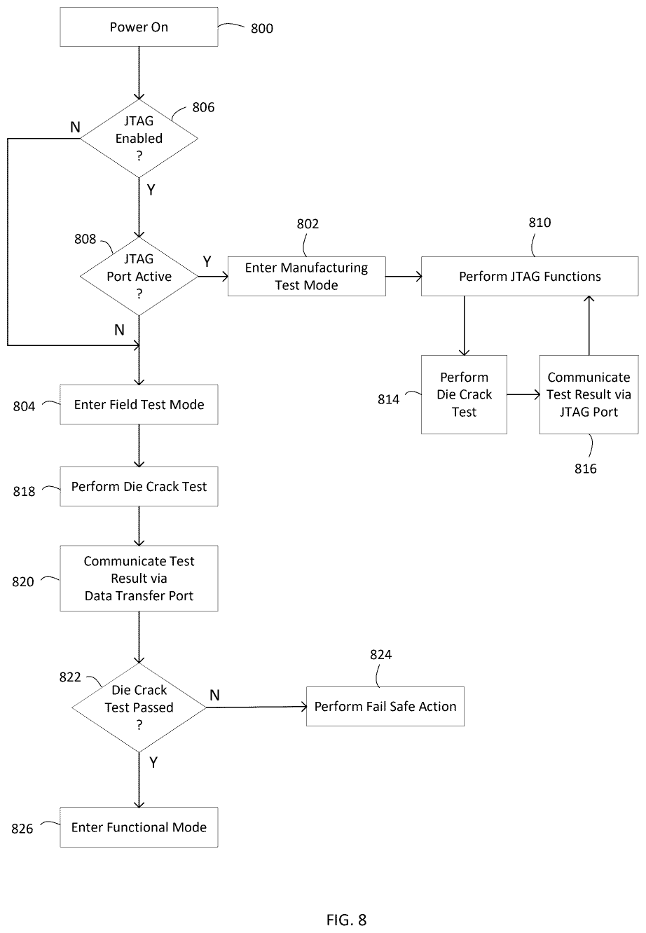

FIG. 7 is a block diagram schematically illustrating an example die crack detection system 700 that includes a host computer system 702 and the integrated circuit package 100 of FIGS. 1 and 2, in accordance with some embodiments. The host computer system may take a variety of forms. In some embodiments (for example, in a manufacturing test environment), the host computer may correspond to an ATE platform. In other embodiments (for example, in field environments), the host computer may correspond to a controller onboard a product that has been released from manufacture and is operating in the field. An example of the latter class of embodiments is a vehicle in which integrated circuit package 100 is mounted to perform a control function in the vehicle and in which the host computer system corresponds to a primary control computer onboard the vehicle.

In any such embodiments, the host computer system includes a central processing unit (“CPU”) 704, a memory controller 706, an input/output (“I/O”) controller 708, and a memory 710. The CPU is coupled to the memory controller and to the I/O controller, is able to write and read data to and from the memory via the memory controller, and is able to write and read data to and from the integrated circuit package via the I/O controller.

The JTAG logic within die crack test logic 208 is coupled to JTAG port 106 via a hardware test controller 712 and a JTAG interface 714. Similarly, the data and control registers within die crack test logic 208 are coupled to data transfer port 108 via the hardware test controller and a data transfer interface 716. By way of example, the high speed interface, the JTAG interface, and the various controllers may be implemented as described in Jagannadha, et al., “Special Session: In-System-Test (IST) Architecture for NVIDIA Drive-AGX Platforms,” 2019 IEEE 37^{th} VLSI Test Symposium (IEEE 2019), the contents of which are hereby incorporated by reference as if entirely set forth herein. In other embodiments, other implementations of those components may be used.

The integrated circuit package also includes functional logic 718, which is distinct from die crack test logic 208. The functional logic is coupled to the data transfer port (via data transfer interface 716) and to the JTAG port (via JTAG interface 714) and may be coupled to the hardware test controller also. The functional logic is both physically and conceptually distinct from the die crack test logic. Whereas the die crack test logic exists to verify the integrity of the integrated package itself, the functional logic exists to perform the operations for which the package was intended in the context of its field application—e.g., to control the operations of a subsystem onboard a vehicle. Thus, as will be further described below, while the die crack test logic is configured to communicate test-related data through one or the other of the JTAG port or the data transfer port of the IC package, the functional logic is configured to communicate non-test data through the data transfer port of the IC package. An example of such non-test data would be data related to the subsystem of the vehicle that the IC package is intended to control while the vehicle is in operation.

In the illustrated embodiment, a die crack test result 724 is communicated from the IC package to the host computer system, either via the JTAG port or via the data transfer port, and is stored at a predetermined location in the memory of the host computer system. This may be accomplished, for example, by means of a direct memory access (“DMA”) transaction initiated by the IC package.

In some embodiments, the test pattern used during the die crack test may be permanently stored or otherwise configured within the IC package itself. In other embodiments, the IC package may retrieve the test pattern to be used during the die crack test from the memory of the host computer system prior to performing the die crack test. In such embodiments, a test pattern may be stored by the host computer system at a predetermined location within its memory for this purpose, as indicated at 726.

In various embodiments, the IC package may include one or more fuse elements 720 operable to enable or disable JTAG functionality in the package. The fuse elements may be placed in a first state when the IC package is being tested in a manufacturing environment so that the JTAG port and the JTAG functionality in the device are enabled and are accessible. Once manufacturing test has been completed, the fuse elements may be placed in a second state in which the JTAG port and the JTAG functionality in the device are disabled and are inaccessible. In such embodiments, once the IC package has been deployed in a field application, the JTAG port of the IC package would no longer be used.

Finally, a boot processor 722 may also be included in the IC package. As will be further described below, the boot processor may be configured to coordinate the activities of the subsystems within the IC package during power on so as to place them in an intended operating state after initial power-on self testing has been completed within the device.

FIG. 8 is a flow diagram illustrating example functionality of IC package 100 in the context of the die crack detection system of FIG. 7. The IC package is configured to operate in at least a manufacturing test mode or in a field test mode. The manufacturing test mode may be used, for example, primarily in a pre-release time frame during which the functional correctness and the physical integrity of the IC package are verified and after which the package may be released from manufacture and deployed in a field application, provided the unit has passed its functional and physical testing. The functionality of the IC package when in manufacturing mode may include, for example, at least its JTAG functionality, but may also include other test-related functionality. The field test mode may be used primarily in a post-release time frame during which the IC package is deployed in a field application.

In some embodiments, the host system may interact with the packaged integrated circuit die as described, for example, in Yilmaz, et al., “NVIDIA MATHS: Mechanism to Access Test-Data over High-Speed Links,” IEEE Design & Test, vol. 40, no. 4, pp. 25-33 (IEEE 2023), the contents of which are hereby incorporated by reference as if entirely set forth herein. In other embodiments, other forms of interaction may be used.

Referring now to the diagram of FIG. 8, when the IC package is initially powered on at step 800, the device enters either the manufacturing test mode 802 or the field test mode 804, depending on whether its JTAG port is enabled (decision 806) and, if so, whether its JTAG port is active (decision 808). If in the manufacturing test mode, the device will perform JTAG functions at step 810, which may include performing a die crack test as described above (step 814), and communicating a result of the die crack test to a host system via its JTAG port (step 816). If in the field test mode, however, the device will perform a die crack test as described above (step 818) and will communicate a result of the die crack test to the host system via its data transfer port (step 820). In embodiments in which the IC package itself is configured to interpret the response pattern as representing a passed or a failed test, the IC package may thereafter perform a fail safe action if a crack in the die has been detected (decision 822 and step 824). An example of such a fail safe operation performed by the IC package itself would be to power itself down or to disable its functional logic. But if it is determined that a crack in the die has not been detected, then the IC package may enter a function mode 826 in which the device begins performing the functions it is intended to perform in its field application.

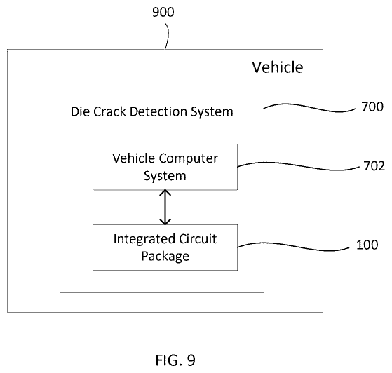

FIG. 9 is a block diagram schematically illustrating an example application of die crack detection system 700 in which IC package 100 is deployed in a vehicle 900, such as in an automobile. In the illustrated example, the vehicle includes a vehicle computer system 902, which in this context may be configured similarly to host computer system 702 and may perform the same functions as described above in relation to the host computer system of FIG. 7.

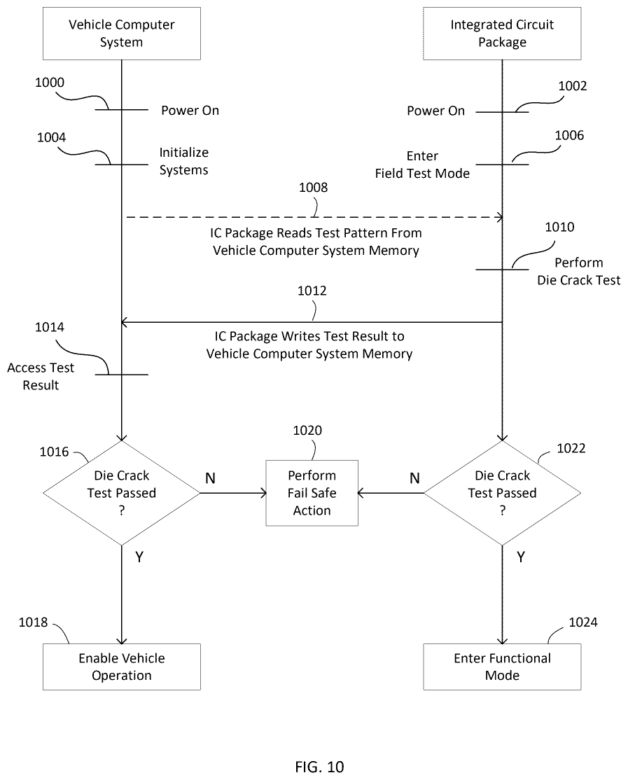

FIG. 10 is a flow diagram illustrating example functionality of the vehicle and die crack detection system of FIG. 9. In the drawing, the functions of the vehicle computer system are illustrated vertically in the left-hand column, while the functions of the IC package are illustrated vertically in the right-hand column. Time proceeds downward in both columns.

At times 1000 and 1002, power is applied to the vehicle computer system and to the IC package, respectively. As the vehicle computer system boots and initializes systems (time 1004), the IC package enters field test mode as described above (time 1006). In embodiments in which a die crack test pattern is stored in the host computer system memory and is retrieved therefrom by the IC package as described above, the IC package may read the test pattern from the vehicle computer system memory at time 1008, such as by means of a DMA transaction. The IC package may then perform a die crack test at time 1010 and may write a result of the die crack test to the vehicle computer system memory, also as described above, at time 1012.

At time 1014, the vehicle computer system accesses the die crack test result from its memory and determines, based on the accessed result, whether or not the die crack test passed (decision 1016). If the vehicle computer system determines that the die crack test passed, then it may enable normal vehicle operation (step 1018). If, on the other hand, the vehicle computer system determines that the die crack test failed, then it may perform a fail safe action (step 1020). A first example of a fail safe operation performed by the vehicle computer system would be to disable operation of the vehicle. A second example would be to indicate that an error has occurred, such as displaying a warning on a user interface of the vehicle and/or by recording the failure in a non-volatile vehicle datastore. In other embodiments, other fail safe operations may be performed by the vehicle computer system.

In embodiments in which the IC package is configured to determine internally whether the die crack test has passed or has failed (decision 1022), the IC package may independently perform a fail safe operation of its own at 1020, such as any of those described above. But if the IC package determines that the die crack test has passed, then it may enter its function mode at 1024.

Multiple specific embodiments have been described above and in the appended claims. Such embodiments have been provided by way of example and illustration. Persons having skill in the art and having reference to this disclosure will perceive various utilitarian combinations, modifications and generalizations of the features and characteristics of the embodiments so described. For example, steps in methods described herein may generally be performed in any order, and some steps may be omitted, while other steps may be added, except where the context clearly indicates otherwise. Similarly, components in structures described herein may be arranged in different positions or locations, and some components may be omitted, while other components may be added, except where the context clearly indicates otherwise. The scope of the disclosure is intended to include all such combinations, modifications, and generalizations as well as their equivalents.

What is claimed is:

1. A system, comprising:
a vehicle having a vehicle computer system and an integrated circuit package communicatively coupled to the vehicle computer system;
wherein the integrated circuit package is configured to perform a die crack test responsive to entering a field test mode and thereafter to produce a die crack test result;
wherein the integrated circuit package is configured to enter the field test mode upon power-up and is further configured to transmit the die crack test result to the vehicle computer system via a data transfer port of the integrated circuit package; and
wherein the vehicle computer system is configured to perform a fail safe action responsive to determining, based on the die crack test result, that the die in the integrated circuit package is cracked.

2. The system of claim 1, wherein:
the fail safe action comprises disabling operation of the vehicle.

3. The system of claim 1, wherein:
the fail safe action comprises indicating that an error has occurred.

4. The system of claim 1, wherein:
the integrated circuit package comprises a Joint Test Action Group (“JTAG”) port; and
the data transfer port is distinct from the JTAG port.

5. The system of claim 1, wherein:
the data transfer port comprises a Peripheral Component Interconnect Express (“PCIe”) port.

6. The system of claim 1, wherein:
the integrated circuit package comprises an elongate conductive trace formed adjacent to at least one peripheral edge of a die disposed in the package; and
the die crack test comprises clocking a digital test pattern into a first end of the conductive trace and receiving a response pattern from a second end of the conductive trace.

7. The system of claim 6, wherein:
the integrated circuit package is configured to store the die crack test result in a memory of the vehicle computer system.

8. The system of claim 7, wherein:
the die crack test result comprises the response pattern.

9. The system of claim 6, wherein:
the integrated circuit package is configured to retrieve the digital test pattern from a memory of the vehicle computer system.

10. An integrated circuit package, comprising:
a die;
an elongate conductive trace formed adjacent to at least one peripheral edge of the die; and
test logic configured to perform a die crack test, wherein performing the die crack test comprises applying a test pattern to a first end of the conductive trace and sensing a response pattern at a second end of the conductive trace;
a Joint Test Action Group (“JTAG”) port coupled to the test logic and accessible from outside of the integrated circuit package; and
a data transfer port, distinct from the JTAG port, also coupled to the test logic and also accessible from outside of the integrated circuit package;
wherein the integrated circuit package is configured to operate in at least two distinct modes comprising:
a manufacturing test mode in which a die crack test result is communicated from the integrated circuit package out of the JTAG port; and
a field test mode in which the die crack test result is communicated from the integrated circuit package out of the data transfer port.

11. The integrated circuit package of claim 10, further comprising:
at least one fuse element that may be activated when manufacturing test is complete and that, once activated, is operable to disable the JTAG port.

12. The integrated circuit package of claim 10, wherein:
the test pattern comprises a first binary sequence; and
the response pattern comprises a second binary sequence.

13. The integrated circuit package of claim 12, wherein:
the die crack test result comprises the response pattern.

14. The integrated circuit package of claim 10:
further comprising functional logic distinct from the test logic;
wherein the integrated circuit package is further configured to operate in a functional mode distinct from the manufacturing test mode and distinct from the field test mode; and
wherein the functional logic is configured to send and receive non-test data through the data transfer port when the integrated circuit package is operating in the functional mode.

15. The integrated circuit package of claim 10, wherein:
the data transfer port comprises a Peripheral Component Interconnect Express (“PCIe”) port.

16. The integrated circuit package of claim 10:
wherein the test logic is configured to transmit the test pattern via a transmit path disposed between the test logic and the first end of the conductive trace, and to receive the response pattern via a receive path disposed between the test logic and the second end of the conductive trace; and
further comprising a JTAG data register coupled to the JTAG port, a field test data register coupled to the data transfer port, and a test pattern multiplexer;
wherein an output of the test pattern multiplexer is coupled to the transmit path, a first input of the test pattern multiplexer is coupled to the field test data register, a second input of the test pattern multiplexer is coupled to the JTAG data register, and a select input of the test pattern multiplexer is coupled to a manufacturing test mode enable signal.

17. The integrated circuit package of claim 16, wherein:
the transmit path comprises a series of one or more diver stages.

18. The integrated circuit package of claim 17, wherein:
the driver stages comprise logical inverters.

19. The integrated circuit package of claim 18 wherein:
the receive path comprises a same number of logical inverters as are contained in the transmit path.

20. The integrated circuit package of claim 10:
further comprising a loopback mode in which the test logic receives the response pattern via a path that bypasses the elongate conductive trace.

21. The integrated circuit package of claim 20, wherein:
the test logic is configured to transmit the test pattern via a transmit path disposed between the test logic and the first end of the conductive trace, and to receive the response pattern via a receive path disposed between the test logic and the second end of the conductive trace;
the receive path comprises an output of a receive path multiplexer;
a first input of the receive path multiplexer is coupled to at least part of the transmit path;
a second input of the receive path multiplexer is coupled to the second end of the conductive trace; and
a select input of the receive path multiplexer is coupled to a loopback mode enable signal.

22. The integrated circuit package of claim 21:
further comprising a field test control register, a JTAG control register, and a loopback enable multiplexer;
wherein a first input of the loopback enable multiplexer is coupled to the field test control register, a second input of the loopback enable multiplexer is coupled to the JTAG control register, an output of the loopback enable multiplexer is coupled to the select input of the receive path multiplexer, and an enable input of the loopback enable multiplexer is coupled to a manufacturing test mode enable signal.

23. The integrated circuit package of claim 10, further comprising:
a static discharge protection diode coupled between the second end of the conductive trace and a ground node.

24. The integrated circuit package of claim 10, further comprising:
a conductive ground trace formed on or in the die and oriented coaxially with the elongate conductive trace.

25. The integrated circuit package of claim 10, further comprising:
an upper conductive trace formed on or in the die above the elongate conductive trace and following an upper path parallel to that of the elongate conductive trace; and
a lower conductive trace formed on or in the die below the elongate conductive trace and following a lower path parallel to that of the elongate conductive trace;
wherein the upper conductive trace and the lower conductive traces are separated from the elongate conductive trace by upper and lower dielectric boundaries, respectively; and
wherein the upper conductive trace and the lower conductive trace are both coupled to an electrical ground.

26. The integrated circuit package of claim 25, further comprising:
a left conductive trace formed on or in the die on a left side of the elongate conductive trace and following a left path parallel to that of the elongate conductive trace; and
a right conductive trace formed on or in the die on a right side of the elongate conductive trace and following a right path parallel to that of the elongate conductive trace;
wherein the left conductive trace and the right conductive traces are separated from the elongate conductive trace by left and right dielectric boundaries, respectively; and
wherein the left conductive trace and the right conductive trace are both coupled to the electrical ground.

27. The integrated circuit package of claim 10, further comprising:
a left conductive trace formed on or in the die on a left side of the elongate conductive trace and following a left path parallel to that of the elongate conductive trace; and
a right conductive trace formed on or in the die on a right side of the elongate conductive trace and following a right path parallel to that of the elongate conductive trace;
wherein the left conductive trace and the right conductive traces are separated from the elongate conductive trace by left and right dielectric boundaries, respectively; and
wherein the left conductive trace and the right conductive trace are both coupled to an electrical ground.
